(19) United States
(12) Patent Application Publication
(10) Pub. No.: US 2016/0286651 A1
(43) Pub. Date: Sep. 29, 2016

(54) CIRCUIT BOARD, MANUFACTURING METHOD THEREOF, AND DISPLAY DEVICE

(71) Applicant: BOE TECHNOLOGY GROUP CO., LTD., Beijing (CN)

(72) Inventors: Defeng MAO, Beijing (CN); Yanbing WU, Beijing (CN)

(21) Appl. No.: 14/905,507

(22) PCT Filed: Jun. 16, 2015
(86) PCT No.: PCT/CN2015/081530

§ 371 Date: Jan. 15, 2016

(30) Foreign Application Priority Data
Dec. 31, 2014 (CN) 201410851782.X

(51) Int. Cl. H05K 1/18; H05K 1/02; H05K 3/30; H05K 1/09; H05K 3/40; H05K 1/11; H05K 1/03

(52) U.S. Cl. CPC H05K 1/18; H05K 1/111; H05K 1/0274; H05K 1/0306; H05K 1/09; H05K 3/4007; H05K 3/30; H05K 2201/10287; H05K 2201/10136; H05K 2201/0326

(57) ABSTRACT

The present invention provides a circuit board, a manufacturing method thereof and a display device. The circuit board comprises a base substrate, a circuit module and a pad, the circuit module and the pad are arranged on the base substrate and are connected. The present invention uses base substrate to replace PCB in the prior art; and therefore, the production cycle of product can be shortened; moreover, the base substrate has a smaller thickness than the PCB, and the thickness of a display device is thus decreased; in the present invention, circuit modules are all provided on the same base substrate, therefore, the space occupied by the circuit modules is decreased, integration is improved, circuit impedance and path length are reduced, and operating speed of the circuit modules is enhanced.

### FIELD OF THE INVENTION

The present invention relates to the field of display technology, in particular to a circuit board, a manufacturing method thereof, and a display device comprising the circuit board.

### BACKGROUND OF THE INVENTION

In the field of display technology, liquid crystal display devices are used more and more widely. FIG. 1 is a schematic diagram of a structure of a liquid crystal display device in the prior art. As shown in FIG. 1, the liquid crystal display device may comprise a liquid crystal display panel 1 and a control circuit. The liquid crystal display panel 1 may comprise a color filter substrate 11 and an array substrate 12, both of which include a base substrate, and the control circuit may comprise a plurality of circuit modules, and the circuit module may be a power supply module 21, a system module 22, a timing control module 23, or the like. The power supply module 21, the system module 22 and the timing control module 23 are arranged on three Printed Circuit Boards (PCBs for short), respectively, the power supply module 21 and the system module 12 are connected to the timing control module 23 via copper wires 24, respectively, and the timing control module 23 is connected to the liquid crystal display panel 1 via a flexible printed circuit board (FPC for short) 25, so that electrical control performance of the liquid crystal display device is achieved.

However, the above-described technical solution in the prior art has the following technical problems:

1) the base substrate in the liquid crystal display panel and the carrier (i.e., PCB) for the circuit modules in the control circuit are made of different materials and are generally manufactured by different manufacturers, which may result in a relatively long production cycle of product;

2) the PCB has a relatively large thickness and needs to be provided on the back of the liquid crystal display panel 1, which increases the thickness of the liquid crystal display device;

3) different circuit modules need to be provided on different PCBs, which leads to large space occupied by the circuit modules (e.g., the power supply module 21, the system module 22, the timing control module 23, or the like), low integration, high circuit impedance, long path length, and slow operation.

### SUMMARY OF THE INVENTION

In view of the above technical problems existing in the prior art, the present invention provides a circuit board and a manufacturing method thereof, and a display device comprising the circuit board, which are used to shorten the production cycle of product, decrease the thickness of a display device and the space occupied by circuit modules, improve integration, reduce circuit impedance and path length, and enhance operating speed of circuit modules.

To achieve the above object, according to one aspect of the present invention, there is provided a circuit board, which comprises a base substrate, a circuit module and a pad, the circuit module and the pad are arranged on the base substrate and the circuit module is connected to the pad.

Optionally, the base substrate is a transparent substrate.

Optionally, material of the base substrate is glass.

Optionally, material of the pad is a transparent conductive material.

Optionally, the circuit board further comprises: a package layer, which is arranged on the circuit module and the pad and covers the base substrate.

Optionally, the circuit board further comprises: a package structure arranged on a package surface of the circuit module, and the package surface of the circuit module faces the base substrate.

Optionally, a pin of the circuit module is connected to the pad.

Optionally, the pin of the circuit module is connected to the pad through a bonding wire.

To achieve the above object, according to another aspect of the present invention, there is provided a display device, which comprises a display panel and any one of the above circuit boards that is connected to the display panel.

To achieve the above object, according to still another aspect of the present invention, there is provided a manufacturing method of a circuit board, which comprises steps of:

arranging a pad on a base substrate;

arranging a circuit module on the base substrate; and

connecting the circuit module to the pad.

Optionally, after the step of connecting the circuit module to the pad, the manufacturing method further comprises a step of: integrally packaging the base substrate by way of dripping from above, so that a package layer is formed on the circuit module and the pad, and covers the base substrate.

Optionally, before the step of arranging a circuit module on the base substrate, the manufacturing method further comprises a step of: forming a package structure on a package surface of the circuit module; and

the step of arranging a circuit module on the base substrate includes: arranging the circuit module on the base substrate such that the package surface of the circuit module faces the base substrate.

Optionally, the step of connecting the circuit module to the pad includes:

connecting a pin of the circuit module to the pad through a bonding wire.

The present invention has the following beneficial effects:

In the technical solutions of the circuit board, the manufacturing method thereof and the display device provided by the present invention, circuit module(s) and pad(s) are arranged on a base substrate and are connected. In the present invention, PCB(s) is replaced by the base substrate, so that the base substrate in the circuit board can be made of the same material as the base substrate in a display panel, as a result, the circuit board and the display panel can be manufactured by the same manufacturer, which can shorten the production cycle of product; the base substrate has a smaller thickness than a PCB, and the thickness of a display device is thus decreased; all the circuit modules are arranged on the same base substrate, which can decrease the space occupied by the circuit modules, improve integration, reduce circuit impedance and path length, and enhance operating speed of the circuit modules.

### BRIEF DESCRIPTION OF THE DRAWINGS

FIG. 1 is a schematic diagram of a structure of a liquid crystal display device in the prior art;

FIG. 2 is a schematic diagram of a structure of a circuit board provided by a first embodiment of the present invention;

FIG. 3 is a schematic diagram of a structure of a display device provided by a second embodiment of the present invention;

FIG. 4 is a flowchart of a manufacturing method of a circuit board provided by a third embodiment of the present invention;

FIG. 5a is a schematic diagram of forming pads on a base substrate in the third embodiment;

FIG. 5b is a schematic diagram of forming circuit modules on the base substrate with the pads formed thereon in the third embodiment; and

FIG. 5c is a schematic diagram of forming a package layer on the base substrate with the circuit modules formed thereon in the third embodiment.

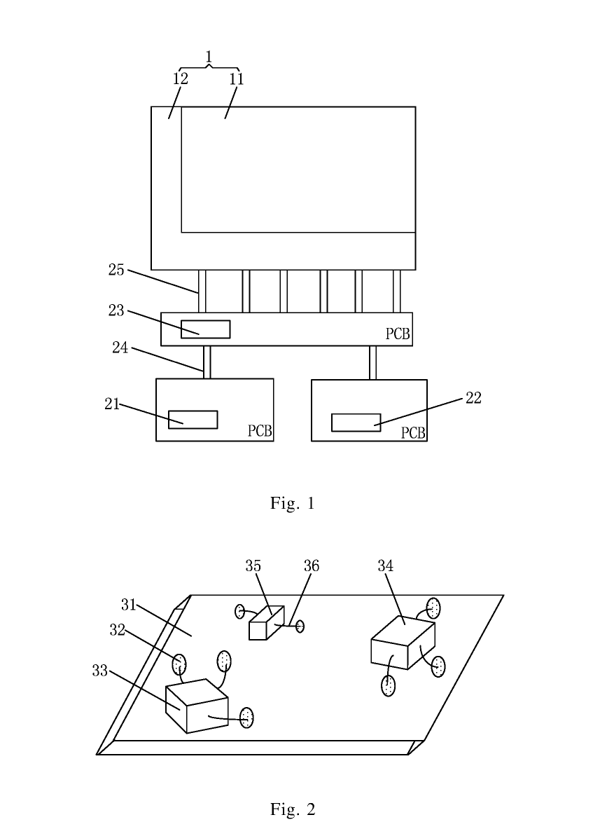

### DESCRIPTION OF THE PREFERRED EMBODIMENT

To enable those skilled in the art to better understand the technical solutions of the present invention, a circuit board, a manufacturing method thereof, and a display device comprising the circuit board provided by the present invention will be described in detail below with reference to the accompanying drawings and specific embodiments.

### First Embodiment

FIG. 2 is a schematic diagram of a structure of a circuit board provided by the first embodiment of the present invention. As shown in FIG. 2, the circuit board includes: a base substrate 31, circuit modules and pads 32, the circuit modules and the pads 32 are arranged on the base substrate 31, and the circuit modules are connected to the pads 32.

The number of the circuit modules may be one or more. This embodiment is described by taking a case where three circuit modules are included as an example, the three circuit modules may be a power supply module 33, a system module 34 and a timing control module 35, and therefore, the base substrate 31 is provided thereon with the power supply module 33, the system module 34 and the timing control module 35. In the embodiment, the circuit module may be other functional module, which is not listed one by one herein.

The base substrate 31 may be a transparent substrate. Specifically, material of the base substrate 31 may be glass.

Material of the pads 32 may be a transparent conductive material, for example, the transparent conductive material may be indium tin oxide (ITO).

The circuit board may further include a package layer (not shown in FIG. 2), the package layer is arranged on the circuit modules and the pads 32 and covers the base substrate 31, so that the base substrate 31, the circuit modules and the pads 32 are packaged as a whole. Material of the package layer may be epoxy resin. By using epoxy resin as packaging material to integrally package the circuit board, package cost can be lowered.

Alternatively, the circuit board may further include a package structure (not shown in FIG. 2), the package structure is arranged on a package surface of the circuit module, and the package surface of the circuit module faces the base substrate 31, that is, the package structure is arranged between the package surface of the circuit module and the surface, on which the circuit module is provided, of the base substrate 31, so that the circuit module is packaged on the base substrate 31. In FIG. 2, the package surface of the circuit module is the lower surface of the circuit module. The material of the package structure is epoxy resin. In this embodiment, the package structure is provided on the package surface of each of the power supply module 33, the system module 34 and the timing control module 35, and the package surface of each of the power supply module 33, the system module 34 and the timing control module 35 faces the base substrate 31.

A pin of the circuit module is connected to the pad 32, and specifically, the pin of the circuit module may be connected to the pad 32 through a bonding wire 36. Each circuit module corresponds to one or more pads, and the number of the pad(s) 32 corresponding to each circuit module is equal to that of the pin(s) of the circuit module, and the pad(s) 32 corresponding to each circuit module is(are) arranged around the circuit module. In this embodiment, the pins of the circuit module are connected to the pads 32 through the bonding wires 36, and specifically, the pins of each of the power supply module 33, the system module 34 and the timing control module 35 are connected to the pads 32 through the bonding wires 36. Since the pin of the circuit module can be connected to the pad 32 through the bonding wire 36, no additional connecting wire needs to be provided between the pin of the circuit module and the pad 32, thereby shortening the distance between the circuit module and the pad. As a result, the distance between the circuit module and the pad can be shorter, and the strength and reliability of connection therebetween are improved.

The circuit board may further include: a wire (not shown in FIG. 2) arranged on the base substrate 31, one end of the wire is connected to the pad 32, and the other end thereof is connected to the display panel.

In the technical solution of the circuit board provided by the embodiment, circuit module(s) and pad(s) are provided on a base substrate and are connected. Compared to a solution in which a circuit module is provided on a PCB in the prior art, in the embodiment, the base substrate is used to replace the PCB in the prior art. As the base substrate in the circuit board may be made of the same material as the base substrate in a display panel, the circuit board and the display panel can be manufactured by the same manufacturer, and therefore, the production cycle of product is shortened; moreover, the base substrate has a smaller thickness than the PCB, and the thickness of a display device is thus decreased, which provides a solution for follow-up development of ultra thin display devices; compared to a solution in which different circuit modules need to be provided on different PCBs in the prior art, in the embodiment, all the circuit modules are provided on the same base substrate, therefore, the space occupied by the circuit modules is decreased, integration is improved, circuit impedance and path length are reduced, and operating speed is enhanced. In the embodiment, the base substrate employs a transparent substrate, the pads are made of transparent conductive material, so that areas other than welding areas (i.e., areas on which the circuit modules are welded) of the circuit board are transparent, which can bring better visual experience to a user compared to the non-transparent PCB in the prior art.

### Second Embodiment

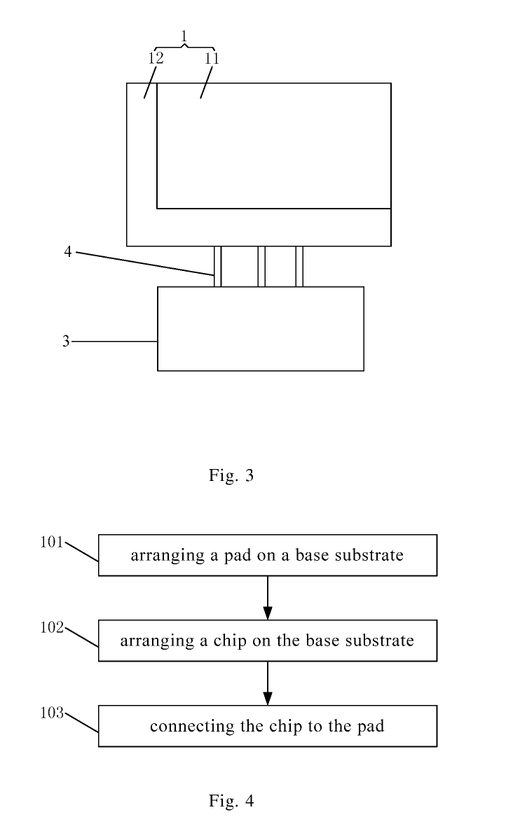

FIG. 3 is a schematic diagram of a structure of a display device provided by the second embodiment of the present invention. As shown in FIG. 3, the display device comprises a display panel 1 and a circuit board 3 connected to the display panel 1. The specific description of the structure of the circuit board 3 may refer to the above first embodiment and FIG. 2, and is not repeated herein.

The display panel 1 may include a color filter substrate 11 and an array substrate 12 opposite to each other. The display panel 1 may be connected to the circuit board 3 via a flexible printed circuit board (FPC for short) 4. In the embodiment, a wire, connected to the pad 32, in the circuit board 3 is connected to the display panel 1 via the FPC 4. Specifically, one end of the wire in the circuit board 3 is connected to the pad 32, the other end of the wire in the circuit board 3 is connected to one end of the FPC 4 via an anisotropic conductive film (ACF for short) (not shown in FIG. 3), and the display panel 1 is connected to the other end of the FPC 4 via the ACF, thereby connecting the display panel 1 to the circuit board 3 via the FPC 4.

In the technical solution of the display device provided by the embodiment, circuit module(s) and pad(s) are provided on a base substrate and are connected. Compared to a solution in which a circuit module is provided on a PCB in the prior art, in the embodiment, the base substrate is used to replace the PCB in the prior art. As the base substrate in the circuit board may be made of the same material as the base substrate in a display panel, the circuit board and the display panel can be manufactured by the same manufacturer, and therefore, the production cycle of product can be shortened; moreover, the base substrate has a smaller thickness than the PCB, and the thickness of a display device is thus decreased, which provides a solution for follow-up development of ultra thin display devices; compared to a solution in which different circuit modules need to be provided on different PCBs in the prior art, in the embodiment, all the circuit modules are provided on the same base substrate, therefore, the space occupied by the circuit modules is decreased, integration is improved, circuit impedance and path length are reduced, and operating speed of the circuit modules is enhanced.

### Third Embodiment

FIG. 4 is a flowchart of a manufacturing method of a circuit board provided by the third embodiment of the present invention, and as shown in FIG. 4, the method may include steps 101 to 103.

At step 101, a pad is arranged on a base substrate.

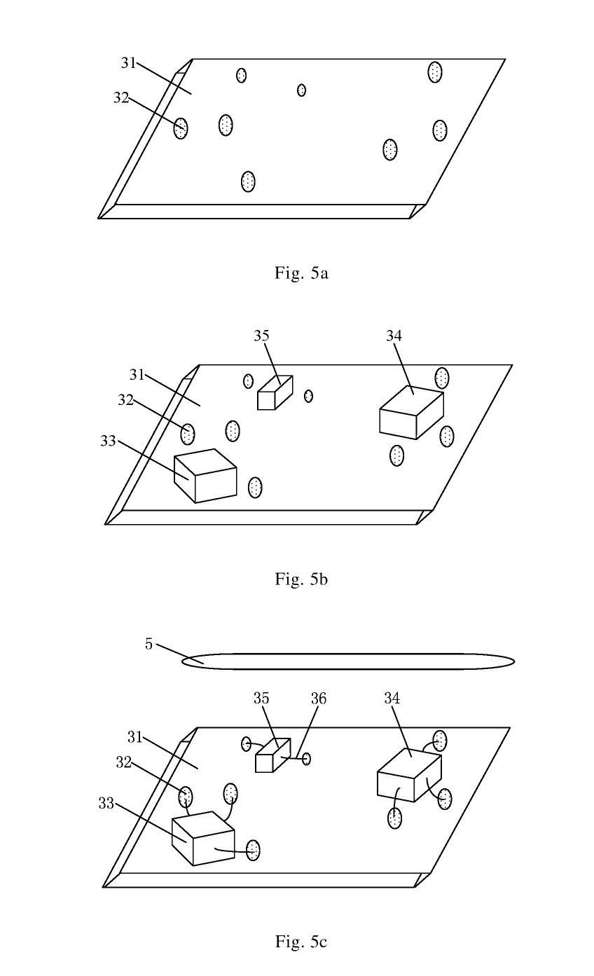

FIG. 5a is a schematic diagram of forming pads 32 on a base substrate 31 in the embodiment. As shown in FIG. 5a, the pads 32 are arranged on the base substrate 31 at preset positions. Specifically, a pad material layer may be deposited on the base substrate 31, and a patterning process is performed on the pad material layer to form the pads 32. Here, the pad material layer may be deposited on the base substrate 31 by magnetron sputtering process.

At step 102, a circuit module is arranged on the base substrate.

FIG. 5b is a schematic diagram of forming circuit modules on the base substrate 31 with the pads 32 formed thereon in the embodiment. As shown in FIG. 5b, the circuit modules are placed on the base substrate 31. Specifically, a power supply module 33, a system module 34 and a timing control module 35 may be placed around the corresponding pads 32, respectively.

At step 103, the circuit module is connected to the pad.

This step may be connecting pins of the circuit modules to the pads. Specifically, as shown in FIG. 2, the pins of each circuit module are connected to the pads 32 through bonding wires 36. In the embodiment, the pins of each of the power supply module 33, the system module 34 and the timing control module 35 are connected to the corresponding pads 32, respectively.

The method may further include step 104.

At step 104, the base substrate is integrally packaged by way of dripping from above, so that a package layer is formed on the circuit module and the pad, and covers the base substrate.

FIG. 5c is a schematic diagram of forming the package layer on the base substrate 31 with the circuit modules formed thereon in the embodiment. As shown in FIG. 5c, the base substrate 31 is integrally packaged by way of dripping from above, so that the package layer 5 is formed on the circuit modules and the pads 32 and covers the base substrate 31.

Optionally, before step 102, the manufacturing method may further include a step of: forming a package structure on a package surface of the circuit module. In this case, arranging a circuit module on the base substrate in step 102 specifically includes: arranging the circuit module on the base substrate such that the package surface of the circuit module faces the base substrate.

In the technical solution of the manufacturing method of a circuit board provided by the embodiment, circuit module(s) and pad(s) are provided on a base substrate and are connected. Compared to a solution in which a circuit module is provided on a PCB in the prior art, in the embodiment, the base substrate is used to replace the PCB in the prior art. As the base substrate in the circuit board may be made of the same material as the base substrate in a display panel, the circuit board and the display panel can be manufactured by the same manufacturer, and therefore, the production cycle of product can be shortened; moreover, the base substrate has a smaller thickness than the PCB, and the thickness of a display device is thus decreased, which provides a solution for follow-up development of ultra thin display devices; compared to a solution in which different circuit modules need to be provided on different PCBs in the prior art, in the embodiment, all the circuit modules are provided on the same base substrate, therefore, the space occupied by the circuit modules is decreased, integration is improved, circuit impedance and path length are reduced, and operating speed is enhanced.

It should be understood that the foregoing implementations are merely exemplary implementations for describing the principle of the present invention, but the present invention is not limited thereto. A person of ordinary skill in the art may make various modifications and improvements without departing from the spirit and essence of the present invention, and these modifications and improvements shall fall into the protection scope of the present invention.

1-12. (canceled)

13. A circuit board, comprising: a base substrate, a circuit module and a pad, wherein the circuit module and the pad are arranged on the base substrate, and the circuit module is connected to the pad.

14. The circuit board according to claim 13, wherein the base substrate is a transparent substrate.

15. The circuit board according to claim 13, wherein material of the base substrate is glass.

16. The circuit board according to claim 14, wherein material of the base substrate is glass.

17. The circuit board according to claim 13, wherein material of the pad is a transparent conductive material.

18. The circuit board according to claim 13, further comprising: a package layer, which is arranged on the circuit module and the pad and covers the base substrate.

19. The circuit board according to claim 13, further comprising: a package structure, wherein the package structure is arranged on a package surface of the circuit module, and the package surface of the circuit module faces the base substrate.

20. The circuit board according to claim 13, wherein a pin of the circuit module is connected to the pad through a bonding wire.

21. A display device, comprising a display panel and a circuit board connected to the display panel, wherein
the circuit board comprises: a base substrate, a circuit module and a pad, the circuit module and the pad are arranged on the base substrate, and the circuit module is connected to the pad.

22. The display device according to claim 21, wherein the base substrate is a transparent substrate.

23. The display device according to claim 21, wherein material of the base substrate is glass.

24. The display device according to claim 22, wherein material of the base substrate is glass.

25. The display device according to claim 21, wherein material of the pad is a transparent conductive material.

26. The display device according to claim 21, further comprising: a package layer, which is arranged on the circuit module and the pad and covers the base substrate.

27. The display device according to claim 21, further comprising: a package structure, wherein the package structure is arranged on a package surface of the circuit module, and the package surface of the circuit module faces the base substrate.

28. The display device according to claim 21, wherein a pin of the circuit module is connected to the pad through a bonding wire.

29. A manufacturing method of a circuit board, comprising steps of:
arranging a pad on a base substrate;
arranging a circuit module on the base substrate; and
connecting the circuit module to the pad.

30. The manufacturing method of a circuit board according to claim 29, further comprising, after the step of connecting the circuit module to the pad, a step of:
integrally packaging the base substrate by way of dripping from above, so that a package layer is formed on the circuit module and the pad and covers the base substrate.

31. The manufacturing method of a circuit board according to claim 29, further comprising, before the step of arranging a circuit module on the base substrate, a step of:
forming a package structure on a package surface of the circuit module; and wherein,
the step of arranging a circuit module on the base substrate comprises: arranging the circuit module on the base substrate such that the package surface of the circuit module faces the base substrate.

32. The manufacturing method of a circuit board according to claim 29, wherein the step of connecting the circuit module to the pad comprises:
connecting a pin of the circuit module to the pad through a bonding wire.
